(19) United States
(12) Patent Application Publication
(10) Pub. No.: US 2012/0058352 A1
(43) Pub. Date: Mar. 8, 2012

(54) METAL SUBSTRATES HAVING CARBON NANOTUBES GROWN THEREON AND METHODS FOR PRODUCTION THEREOF

(75) Inventors: Tushar K. SHAH, Columbia, MD (US); Brandon K. Malet, Baltimore, MD (US); Jigar M. Patel, Perryville, MD (US)

(73) Assignee: APPLIED NANOSTRUCTURED SOLUTIONS, LLC, Baltimore, MD (US)

(21) Appl. No.: 13/042,397

(22) Filed: Mar. 7, 2011

Related U.S. Application Data
(60) Provisional application No. 61/379,713, filed on Sep. 2, 2010.

(51) Int. Cl. C23C 16/02; B32B 15/04; B82Y 30/00; B82Y 40/00

(52) U.S. Cl. 428/457; 427/249.1; 977/734; 977/843; 977/902

(57) ABSTRACT

The present disclosure describes methods for growing carbon nanotubes on metal substrates. The methods include depositing a catalytic material on a metal substrate to form a catalyst-laden metal substrate; optionally depositing a non-catalytic material on the metal substrate prior to, after, or concurrently with the catalytic material; conveying the catalyst-laden metal substrate through a carbon nanotube growth reactor having carbon nanotube growth conditions therein; and growing carbon nanotubes on the catalyst-laden metal substrate. The catalyst-laden metal substrate can optionally remain stationary while the carbon nanotubes are being grown. The catalytic material can be a catalyst or a catalyst precursor. The catalytic material and the optional non-catalytic material can be deposited on the metal substrate from one or more solutions by, for example, spray coating or dip coating techniques.

### CROSS-REFERENCE TO RELATED APPLICATIONS

This application claims the benefit of priority under 35 U.S.C. §119 from U.S. Provisional Patent Application Ser. No. 61/379,713, filed Sep. 2, 2010, which is incorporated herein by reference in its entirety.

### STATEMENT REGARDING FEDERALLY SPONSORED RESEARCH OR DEVELOPMENT

Not applicable.

### FIELD OF THE INVENTION

The present invention generally relates to carbon nanotubes, and, more specifically, to carbon nanotube growth.

### BACKGROUND

In order to synthesize carbon nanotubes, a catalyst is generally needed to mediate carbon nanotube growth. Most often the catalyst is a metal nanoparticle, particularly a zero-valent transition metal nanoparticle. A number of methods for synthesizing carbon nanotubes are known including, for example, micro-cavity, thermal- or plasma-enhanced chemical vapor deposition (CVD) techniques, laser ablation, arc discharge, flame synthesis, and high pressure carbon monoxide (HiPCO) techniques.

Synthesis of carbon nanotubes on solid substrates can be carried out using many of these techniques. Often, the solid substrate is a refractory substance such as, for example, silicon dioxide or aluminum oxide. However, it is considered very difficult in the art to grow carbon nanotubes on metal substrates. There are several reasons for this difficulty. First, some metals have melting points that are in the temperature range at which carbon nanotubes typically form (about 550° C. to about 800° C.), thereby rendering the metal substrate susceptible to thermal damage. Damage can include cracking, warping, pitting and thinning, particularly in thin substrates. Even in a metal substrate having a melting point in excess of the carbon nanotube growth temperature, extended exposure to carbon nanotube growth conditions can compromise the metal substrate's structural integrity by forming the same types of thermal damage. Further, interactions between the metal catalyst and the metal substrate can severely limit the diffusion of atomic carbon into the metal catalyst, thereby significantly limiting or prohibiting carbon nanotube growth.

Carbon nanotubes have been proposed to have utility in a number of applications, many of which would be particularly well suited for carbon nanotubes grown on metal substrates. In view of the foregoing, reliable methods for growing carbon nanotubes on metal substrates would be of substantial benefit in the art. The present disclosure satisfies this need and provides related advantages as well.

### SUMMARY

In various embodiments, continuous carbon nanotube growth processes conducted in a reactor for synthesizing carbon nanotubes and having carbon nanotube growth conditions therein are described. The methods include depositing a catalytic material on a metal substrate to form a catalyst-laden metal substrate, depositing a non-catalytic material on the metal substrate, conveying the catalyst-laden metal substrate through the reactor in a continuous manner, and growing carbon nanotubes on the catalyst-laden metal substrate. The non-catalytic material is deposited prior to, after, or concurrently with the catalytic material.

In some embodiments, carbon nanotube growth processes conducted in a reactor for synthesizing carbon nanotubes and having carbon nanotube growth conditions therein include depositing a catalytic material on a metal substrate having a melting point in excess of about 800° C. from a solution to form a catalyst-laden metal substrate, and growing carbon nanotubes on the catalyst-laden metal substrate. The catalyst-laden metal substrate remains stationary or is conveyed through the reactor in a continuous manner while growing carbon nanotubes thereon.

In some embodiments, continuous carbon nanotube growth processes conducted in a reactor for synthesizing carbon nanotubes and having carbon nanotube growth conditions therein include depositing a catalyst precursor on a metal substrate from a solution to form a catalyst-laden metal substrate, depositing a non-catalytic material on the metal substrate from a solution, and conveying the catalyst-laden metal substrate through the reactor in a continuous manner while growing carbon nanotubes thereon. The non-catalytic material is deposited prior to, after or concurrently with the catalyst precursor.

In some embodiments, metal substrates containing carbon nanotubes grown thereon are produced by the carbon nanotube growth processes described herein.

The foregoing has outlined rather broadly the features of the present disclosure in order that the detailed description that follows can be better understood. Additional features and advantages of the disclosure will be described hereinafter, which form the subject of the claims.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIGS. 1A and 1B show illustrative SEM images of carbon nanotubes grown on a copper substrate using a palladium catalyst under static chemical vapor deposition conditions for 5 minutes at a temperature of 750° C.;

FIG. 2 shows an illustrative SEM image of carbon nanotubes grown on a copper substrate using a palladium catalyst under continuous chemical vapor deposition conditions for 1 minute at a temperature of 750° C. and a linespeed of 1 ft/min, which is equivalent to 1 minute of carbon nanotube growth time;

FIGS. 3A and 3B show illustrative SEM images of carbon nanotubes grown on a copper substrate using an iron nanoparticle catalyst under static chemical vapor deposition conditions for 5 minutes at a temperature of 750° C., where the iron nanoparticle catalyst was deposited over a layer of non-catalytic Accuglass T-11 Spin-On Glass;

FIGS. 4A and 4B show illustrative SEM images of carbon nanotubes and carbon nanofibers grown on a copper substrate using an iron nanoparticle catalyst under static chemical vapor deposition conditions for 30 minutes at a temperature of 750° C., where the iron nanoparticle catalyst was deposited under a layer of non-catalytic Accuglass T-11 Spin-On Glass;

FIGS. 5A and 5B show illustrative SEM images of carbon nanotubes grown on a stainless steel wire mesh substrate using an iron nanoparticle catalyst under continuous chemical vapor deposition conditions at a temperature of 800° C. and a linespeed of 2 ft/min, which is equivalent to 30 seconds of carbon nanotube growth time, where the iron nanoparticle catalyst was deposited under a layer of non-catalytic Accuglass T-11 Spin-On Glass; and

FIGS. 6A and 6B show illustrative SEM images of carbon nanotubes grown on a copper substrate using an iron nitrate catalyst under static chemical vapor deposition conditions for 5 minutes at a temperature of 750° C., where the iron nitrate catalyst was deposited concurrently with a non-catalytic aluminum nitrate material.

### DETAILED DESCRIPTION

The present disclosure is directed, in part, to processes for growing carbon nanotubes on metal substrates. The present disclosure is also directed, in part, to metal substrates containing carbon nanotubes grown thereon that are produced by the present carbon nanotube growth processes. Carbon nanotube growth processes of the present disclosure can be conducted with the metal substrate being held stationary in batchwise processing or with the metal substrate being continuously conveyed through a carbon nanotube synthesis reactor in continuous processes.

In various embodiments, the carbon nanotube growth processes described herein can be conducted in a substantially continuous manner. Given the benefit of the present disclosure, one of ordinary skill in the art will recognize the benefits of a substantially continuous carbon nanotube growth process. Among the many advantages of the present continuous carbon nanotube growth processes are 1) limiting thermal damage to metal substrates and 2) the ability to grow sufficiently large quantities of carbon nanotubes for commercial applications. In spite of these advantages of continuous carbon nanotube growth processes, it should also be understood that the present carbon nanotube growth processes can be conducted in a batchwise (static) manner in alternative embodiments.

Carbon nanotubes have demonstrated utility in a number of applications that take advantage of their unique structure and properties including, for example, large surface area, mechanical strength, electrical conductivity, and thermal conductivity. When grown on a metal substrate, carbon nanotubes and the metal substrate form a composite architecture that advantageously allows the beneficial properties of the carbon nanotubes to be imparted to the metal substrate. However, growth of carbon nanotubes on metal substrates has proved particularly difficult in the art.

As a non-limiting example of the benefits that can be conveyed to a metal substrate by carbon nanotubes, the mechanical properties of a metal substrate can be improved by growing carbon nanotubes thereon. Such metal substrates can be particularly useful for structural applications due to their improved fracture toughness and fatigue resistance, for example. Metals including, for example, copper, nickel, platinum, silver, gold, and aluminum have a face centered cubic (fcc) atomic structure that is particularly susceptible to fatigue failure. Growth of carbon nanotubes on these metals, in particular, or other metals having an fcc atomic structure can markedly improve their mechanical strength by preventing fatigue cracks from propagating, thereby increasing the number of stress cycles that the metal can undergo before experiencing fatigue failure.

Another non-limiting example of the benefits that carbon nanotubes can convey to a metal substrate is an enhancement of the metal's electrical properties. For example, metal films used as current collectors in batteries can exhibit improved current collection properties when carbon nanotubes are grown thereon. Metal substrates containing carbon nanotubes grown thereon can also be used as electrodes in supercapacitors and other electrical devices. Not only do the carbon nanotubes improve the electrical conductivity of the electrodes, but they also increase the overall electrode surface area and further increase its efficiency.

In some embodiments, carbon nanotubes grown on a metal substrate can be chemically or mechanically adhered to the metal substrate. Carbon nanotubes grown on a metal substrate by the present methods (i.e., infused carbon nanotubes) are more strongly adhered to the metal substrate than would pre-synthesized carbon nanotubes held in place by simple van der Waals physiosorption interactions. Hence, the present metal substrates having carbon nanotubes grown thereon are distinguished from metal substrates having had pre-formed carbon nanotubes deposited thereon (e.g., from a carbon nanotube solution or suspension). In some embodiments, the carbon nanotubes can be directly bonded to the metal substrate. In other embodiments, the carbon nanotubes can be indirectly bonded to the metal substrate via a catalytic material used to mediate the carbon nanotubes' synthesis and/or via a non-catalytic material deposited on the metal substrate.

As used herein, the term “nanoparticle” refers to particles having a diameter between about 0.1 nm and about 100 nm in equivalent spherical diameter, although nanoparticles need not necessarily be spherical in shape. As used herein, the term “catalytic nanoparticle” refers to a nanoparticle that possesses catalytic activity for mediating carbon nanotube growth.

As used herein, the term “transition metal” refers to any element or alloy of elements in the d-block of the periodic table (Groups 3 through 12), and the term “transition metal salt” refers to any transition metal compound such as, for example, transition metal oxides, nitrates, chlorides, bromides, iodides, fluorides, acetates, carbides, nitrides, and the like. Illustrative transition metals that form catalytic nanoparticles suitable for synthesizing carbon nanotubes include, for example, Ni, Fe, Co, Mo, Cu, Pt, Au, Ag, alloys thereof, salts thereof, and mixtures thereof.

As used herein, the terms “spoolable lengths” or “spoolable dimensions” equivalently refer to a material that has at least one dimension that is not limited in length, thereby allowing the material to be stored on a spool or mandrel. A material of “spoolable lengths” or “spoolable dimensions” has at least one dimension that allows the continuous growth of carbon nanotubes thereon. However, a material of spoolable lengths can also be processed in a batchwise manner, if desired.

As used herein, the term “continuous carbon nanotube growth process” refers to a multi-stage process for growing carbon nanotubes that operates in a substantially uninterrupted manner, thereby allowing a metal substrate to have carbon nanotubes grown over its length by conveying the metal substrate through a carbon nanotube synthesis reactor. In some embodiments, the metal substrate in a continuous carbon nanotube growth process can be of spoolable lengths.

As used herein, the terms “convey” and “conveying” refer to moving or transporting.

As used herein, the term “catalytic material” refers to catalysts and catalyst precursors. As used herein, the term “catalyst precursor” refers to a substance that can be transformed into a catalyst under appropriate conditions.

In various embodiments, continuous carbon nanotube growth processes conducted in a reactor for synthesizing carbon nanotubes and having carbon nanotube growth conditions therein are described. The methods include depositing a catalytic material on a metal substrate to form a catalyst-laden metal substrate, depositing a non-catalytic material on the metal substrate, conveying the catalyst-laden metal substrate through the reactor in a continuous manner, and growing carbon nanotubes on the catalyst-laden metal substrate. The non-catalytic material is deposited prior to, after, or concurrently with the catalytic material.

In some embodiments, continuous carbon nanotube growth processes conducted in a reactor for synthesizing carbon nanotubes and having carbon nanotube growth conditions therein include depositing a catalyst precursor on a metal substrate from a solution to form a catalyst-laden metal substrate, depositing a non-catalytic material on the metal substrate from a solution, and conveying the catalyst-laden metal substrate through the reactor in a continuous manner while growing carbon nanotubes thereon. The non-catalytic material is deposited prior to, after or concurrently with the catalyst precursor.

In some embodiments, carbon nanotube growth processes conducted in a reactor for synthesizing carbon nanotubes and having carbon nanotube growth conditions therein include depositing a catalytic material on a metal substrate having a melting point in excess of about 800° C. from a solution to form a catalyst-laden metal substrate, and growing carbon nanotubes on the catalyst-laden metal substrate. The catalyst-laden metal substrate remains stationary or is conveyed through the reactor in a continuous manner while growing carbon nanotubes thereon.

The types of carbon nanotubes grown on the metal substrates can generally vary without limitation. In various embodiments, the carbon nanotubes grown on the metal substrates can be, for example, any of a number of cylindrically-shaped allotropes of carbon of the fullerene family including single-wall carbon nanotubes, double-wall carbon nanotubes, multi-wall carbon nanotubes, and any combination thereof. One of ordinary skill in the art will recognize that the types of carbon nanotubes grown on the metal substrate can be varied by adjusting the carbon nanotube growth conditions. In some embodiments, the carbon nanotubes can be capped with a fullerene-like structure. That is, the carbon nanotubes have closed ends in such embodiments. However, in other embodiments, the carbon nanotubes can remain open-ended. In some embodiments, closed carbon nanotube ends can be opened through treatment with an appropriate oxidizing agent (e.g., HNO₃/H₂SO₄). In some embodiments, the carbon nanotubes can encapsulate other materials after being grown on the metal substrate. In some embodiments, the carbon nanotubes can be covalently functionalized after being grown on the metal substrate. In some embodiments, a plasma process can be used to promote functionalization of the carbon nanotubes.

Carbon nanotubes can be metallic, semimetallic or semiconducting depending on their chirality. An established system of nomenclature for designating a carbon nanotube's chirality is recognized by those of ordinary skill in the art and is distinguished by a double index (n,m), where n and m are integers that describe the cut and wrapping of hexagonal graphite when formed into a tubular structure. In various embodiments, carbon nanotubes grown on metal substrates according to the present embodiments can be of any specified chirality or mixture of chiral forms.

In addition to chirality, a carbon nanotube's diameter also influences its electrical conductivity and the related property of thermal conductivity. In the synthesis of carbon nanotubes, a carbon nanotube's diameter can be controlled by using catalytic nanoparticles of a given size. Typically, a carbon nanotube's diameter is approximately that of the catalytic nanoparticle that catalyzes its formation. Therefore, a carbon nanotube's properties can be controlled in one respect by adjusting the size of the catalytic nanoparticle used for its synthesis, for example. By way of non-limiting example, catalytic nanoparticles having a diameter of about 1 nm to about 5 nm can be used to grow predominantly single-wall carbon nanotubes. Larger catalytic nanoparticles can be used to prepare predominantly multi-wall carbon nanotubes, which have larger diameters because of their multiple nanotube layers. Mixtures of single-wall and multi-wall carbon nanotubes can also be grown by using larger catalytic nanoparticles in the carbon nanotube synthesis.

In various embodiments herein, the diameter of the carbon nanotubes grown on a metal substrate can range between about 1 nm and about 500 nm. In some embodiments, the diameter of the carbon nanotubes can range between about 1 nm and about 10 nm. In other embodiments, the diameter of the carbon nanotubes can range between about 1 nm and about 30 nm, or between about 5 nm and about 30 nm, or between about 15 nm and about 30 nm. In some embodiments, the diameter of the carbon nanotubes can range between about 10 nm and about 50 nm or between about 50 nm and about 100 nm. In other embodiments, the diameter of the carbon nanotubes can range between about 100 nm and about 300 nm or between about 300 nm and about 500 nm. Higher loadings of catalytic material tend to favor larger carbon nanotube diameters, particularly those greater than about 100 nm in diameter. In addition, for a given loading of catalytic material, different carbon nanotube diameters can be obtained depending on whether the carbon nanotube synthesis is conducted in a continuous or batchwise manner.

In some embodiments, an average length of the carbon nanotubes grown on the metal substrate can be between about 1 μm and about 500 μm, including about 1 μm, about 2 μm, about 3 μm, about 4 μm, about 5 μm, about 6 μm, about 7 μm, about 8 μm, about 9 μm, about 10 μm, about 15 μm, about 20 μm, about 25 μm, about 30 μm, about 35 μm, about 40 μm, about 45 μm, about 50 μm, about 60 μm, about 70 μm, about 80 μm, about 90 μm, about 100 μm, about 150 μm, about 200 μm, about 250 μm, about 300 μm, about 350 μm, about 400 μm, about 450 μm, about 500 μm, and all values and subranges therebetween. In some embodiments, an average length of the carbon nanotubes can be less than about 1 μm, including about 0.5 μm, for example, and all values and subranges therebetween. In some embodiments, an average length of the carbon nanotubes can be between about 1 μm and about 10 μm, including, for example, about 1 μm, about 2 μm, about 3 μm, about 4 μm, about 5 μm, about 6 μm, about 7 μm, about 8 μm, about 9 μm, about 10 μm, and all values and subranges therebetween. In still other embodiments, an average length of the carbon nanotubes is greater than about 500 μm, including, for example, about 510 μm, about 520 μm, about 550 μm, about 600 μm, about 700 μm, about 800 μm, about 900 μm, about 1000 μm, and all values and subranges therebetween.

In some embodiments, the catalytic material of the present methods can be a catalyst or a catalyst precursor. That is, the catalytic material can directly catalyze the formation of carbon nanotubes, or it can be a substance that is converted into a catalyst either prior to or during exposure to carbon nanotube growth conditions in the reactor for synthesizing carbon nanotubes.

In various embodiments, the catalytic material can be a transition metal, a transition metal alloy, a transition metal salt, or a combination thereof. In some embodiments, the catalytic material can be in the form of catalytic nanoparticles. In some embodiments, the catalytic material can be a transition metal salt or a combination of transition metal salts such as, for example, a transition metal nitrate, a transition metal acetate, a transition metal chloride, a transition metal fluoride, a transition metal bromide, or a transition metal iodide. In alternative embodiments, transition metal carbides, transition metal nitrides, or transition metal oxides can be used as the catalytic material. Illustrative transition metal salts suitable for practicing the present methods include, for example, iron (II) nitrate, iron (III) nitrate, cobalt (III) nitrate, nickel (II) nitrate, copper (II) nitrate, iron (II) acetate, iron (III) acetate, cobalt (III) acetate, nickel (II) acetate, copper (II) acetate, iron (II) chloride, iron (III) chloride, cobalt (III) chloride, nickel (II) chloride, copper (II) chloride, and combinations thereof. Hydrates of these transition metal salts can also be used. In still other embodiments, the catalytic material can include substances such as, for example, palladium, FeO, Fe₂O₃, Fe₃O₄, and combinations thereof, any of which can be in the form of nanoparticles.

In some embodiments, a non-catalytic material can also be used in the present methods in conjunction with the catalytic material. Although carbon nanotubes can be grown on metal substrates by employing the present methods even in the absence of a non-catalytic material, use of a non-catalytic material in conjunction with the catalytic material generally results in improved carbon nanotube growth rates. Without being bound by theory or mechanism, it is believed that the non-catalytic material limits interactions of the catalytic material with the metal substrate that can otherwise inhibit carbon nanotube growth. Further, it is also believed that the non-catalytic material can facilitate the dissociation of a catalyst precursor into an active catalyst. In addition, the non-catalytic material can act as a thermal barrier to protect the surface of the metal substrate and shield it from damage during carbon nanotube growth.

The use of a non-catalytic material in conjunction with a catalyst precursor can enable the growth of carbon nanotubes on a metal substrate without a separate operation to convert the catalyst precursor into an active catalyst suitable for carbon nanotube growth. That is, a catalyst precursor can be used in conjunction with a non-catalytic material in the present methods to directly grow carbon nanotubes on a metal substrate upon exposure to carbon nanotube growth conditions. In alternative embodiments, however, a separate treatment operation (e.g., heating) of the catalyst precursor can be used, if desired, to convert the catalyst precursor into an active catalyst prior to exposure to carbon nanotube growth conditions. In some embodiments, the present methods include forming catalytic nanoparticles from a catalyst precursor while the catalyst-laden metal substrate is being exposed to carbon nanotube growth conditions in the reactor. In some embodiments, the present methods include forming catalytic nanoparticles from the catalyst precursor while the catalyst-laden metal substrate is being conveyed through the reactor. In alternative embodiments, the present methods include forming catalytic nanoparticles from a catalyst precursor prior to exposing the catalyst-laden metal substrate to carbon nanotube growth conditions in the reactor, such as by heating the catalyst precursor on the catalyst-laden metal substrate. In some embodiments, the present methods include forming catalytic nanoparticles from the catalyst precursor prior to conveying the catalyst-laden metal substrate through the reactor.

Non-catalytic materials that are suitable for practicing the present methods are generally substances that are inert to carbon nanotube growth conditions. As described above, such non-catalytic materials are further operable to stabilize the catalytic material, thereby facilitating carbon nanotube growth. In some embodiments, the non-catalytic material can be an aluminum-containing compound or a silicon-containing compound. Illustrative aluminum-containing compounds include aluminum salts (e.g., aluminum nitrate and/or aluminum acetate), including hydrates thereof. Illustrative silicon-containing compounds include glasses and like silicon dioxide formulations, silicates and silanes. In some embodiments, an alkoxysilane, an alumoxane, alumina nanoparticles, spin on glass, or glass nanoparticles can be used as the non-catalytic material.

When a non-catalytic material is used in the present methods, the catalytic material can be deposited prior to, after, or concurrently with the catalytic material. In some embodiments, the catalytic material is deposited prior to the non-catalytic material. That is, in such embodiments, the catalytic material is deposited between the metal substrate and the non-catalytic material. In other embodiments, the catalytic material is deposited after the non-catalytic material. That is, in such embodiments, the non-catalytic material is deposited between the metal substrate and the catalytic material. In still other embodiments, the catalytic material is deposited concurrently with the non-catalytic material. Regardless of the deposition sequence, the combination of the catalytic material and the non-catalytic material form a catalyst coating on the metal substrate. In some embodiments, the catalyst coating has a thickness ranging between about 10 nm and about 1 μm. In other embodiments, the catalyst coating has a thickness ranging between about 10 nm and about 100 nm or between about 10 nm and about 50 nm.

In some embodiments, the catalytic material and the non-catalytic material can be deposited by a technique or combination of techniques such as, for example, spray coating, dip coating, or a like solution-based deposition technique. In some embodiments, the catalytic material and the non-catalytic material can be deposited from at least one solution. In some embodiments, the catalytic material can be deposited from a first solution, and the non-catalytic material can be deposited from a second solution. In such embodiments, the catalytic material can be deposited prior to or after the non-catalytic material. In other embodiments, the catalytic material and the non-catalytic material can be deposited concurrently from the same solution.

In some embodiments, the catalytic material and the non-catalytic material each have a concentration in the at least one solution ranging between about 0.1 mM and about 1.0 M. In other embodiments, the catalytic material and the non-catalytic material each have a concentration in the at least one solution ranging between about 0.1 mM and about 50 mM, or between about 10 mM and about 100 mM, or between about 50 mM and about 1.0 M. When the catalytic material and the non-catalytic material are in the same solution, the referenced concentration ranges refer to the concentration of each component in the solution, rather than the overall solution concentration. Solution concentrations ranging between about 10 mM and about 100 mM for each component are typically most reliable for mediating carbon nanotube growth on a metal substrate, although this range can vary based on the identities of the metal substrate, the catalytic material and the non-catalytic material.

The solvent(s) used in the at least one solution can generally vary without limitation, provided that they effectively solubilize or disperse the catalytic material and the non-catalytic material, if present. Particularly suitable solvents include, for example, water, alcohols (e.g., methanol, ethanol, or isopropanol), esters (e.g., methyl acetate or ethyl acetate), ketones (e.g., acetone or butanone), and mixtures thereof. In some embodiments, a small amount of a co-solvent can be added to achieve solubility of a transition metal salt in a solvent in which the salt is otherwise not sufficiently soluble. Illustrative examples of such co-solvents include, for example, glyme, diglyme, triglyme, dimethylformamide, and dimethylsulfoxide. Generally, solvents having a relatively low boiling point are preferred such that the solvent can be easily removed prior to exposure of the metal substrate to the carbon nanotube growth conditions. Ready removal of the solvent can facilitate the formation of a homogenous coating of the catalytic material. In higher boiling point solvents or those that tend to pond on the surface of the metal substrate, a non-uniform distribution of the catalytic material can occur, thereby leading to poor carbon nanotube growth.

Although inclusion of a non-catalytic material is generally advantageous in the present methods, there can be an upper limit in the amount of non-catalytic material above which carbon nanotube growth becomes infeasible. This can be particularly true when the non-catalytic material is deposited after or concurrently with the catalytic material. Such a limit does not necessarily apply when the non-catalytic material is deposited prior to the catalytic material. If too much non-catalytic material is included, the non-catalytic material can overcoat the catalytic material, thereby inhibiting diffusion of a carbon feedstock gas into the catalytic material and blocking carbon nanotube growth. In some embodiments, a molar ratio of the non-catalytic material to the catalytic material is at most about 6:1. In other embodiments, a molar ratio of the non-catalytic material to the catalytic material is at most about 2:1.

Metal substrates of the present methods can generally vary without limitation, provided that they are not substantially damaged by the carbon nanotube growth conditions. In various embodiments, carbon nanotube growth conditions of the present disclosure involve a temperature ranging between about 550° C. and about 800° C. to permit rapid carbon nanotube growth rates of up to about 5 μm/sec. Further details of carbon nanotube growth conditions and reactors for carbon nanotube growth are set forth hereinbelow. Although certain metals have melting points within or only slightly above this temperature range, even low melting metal substrates (e.g., melting points of less than about 800° C.) can be substantially undamaged during brief exposure times to the carbon nanotube growth conditions. However, the present methods can generally be used to grow longer carbon nanotubes on high melting metal substrates (e.g., melting points of greater than about 800° C.) by taking advantage of longer exposure times to carbon nanotube growth conditions. As previously noted, however, metal substrate damage can still occur if care is not taken during carbon nanotube growth, even in metal substrates having a melting point in excess of the carbon nanotube growth temperature.

In some embodiments, metal substrates of the present methods have a melting point in excess of about 800° C. Illustrative metal substrates having a melting point in excess of about 800° C. that can be used in practicing the present methods include, for example, copper (mp 1084° C.), tungsten (mp 3400° C.), platinum (mp 1770° C.), titanium (mp 1670° C.), iron (mp 1536° C.), steel and stainless steel alloys (mp 1510° C.), nickel (mp 1453° C.), nickel-chromium alloys (e.g., ICONEL alloys, a registered trademark of Special Metals Corporation, mp 1390° C.-1425° C.), nickel-copper alloys (e.g., MONEL alloys, a registered trademark of Special Metals Corporation, mp 1300° C.-1350° C.), gold (mp 1063° C.), silver (mp 961° C.), and brass alloys (mp 930° C.).

The form of the metal substrate can vary without limitation in the present embodiments. Generally, the form of the metal substrate is compatible with a continuous carbon nanotube growth process. In some embodiments, the metal substrate can be in non-limiting forms such as, for example, metal fibers, metal filaments, metal wires, metal rovings, metal yarns, metal fiber tows, metal tapes, metal ribbons, metal wire meshes, metal tubes, metal films, metal braids, woven metal fabrics, non-woven metal fabrics, metal fiber plies, and metal fiber mats. Higher order forms such as, for example, woven and non-woven metal fabrics, metal fiber plies, and metal wire meshes can be formed from lower order metal substrates such as, for example, metal fibers, metal filaments, and metal fiber tows. That is, metal fibers, metal filaments, or metal fiber tows can have carbon nanotubes grown thereon, with formation of the higher order forms taking place thereafter. In other embodiments, such higher order forms can be preformed with growth of carbon nantubes thereon taking place thereafter.

Filaments include high aspect ratio fibers having diameters generally ranging in size between about 1 μm and about 100 μm. Rovings include soft strands of fiber that have been twisted, attenuated and freed of foreign matter.

Fiber tows are generally compactly associated bundles of filaments, which can be twisted together to give yarns in some embodiments. Yarns include closely associated bundles of twisted filaments, wherein each filament diameter in the yarn is relatively uniform. Yarns have varying weights described by their ‘tex,’ (expressed as weight in grams per 1000 linear meters), or ‘denier’ (expressed as weight in pounds per 10,000 yards). For yarns, a typical tex range is usually between about 200 and about 2000.

Fiber braids represent rope-like structures of densely packed fibers. Such rope-like structures can be assembled from yarns, for example. Braided structures can include a hollow portion. Alternately, a braided structure can be assembled about another core material.

Fiber tows can also include associated bundles of untwisted filaments. As in yarns, filament diameter in a fiber tow is generally uniform. Fiber tows also have varying weights and a tex range that is usually between about 200 and 2000. In addition, fiber tows are frequently characterized by the number of thousands of filaments in the fiber tow, such as, for example, a 12K tow, a 24K tow, a 48K tow, and the like.

Tapes are fiber materials that can be assembled as weaves or as non-woven flattened fiber tows, for example. Tapes can vary in width and are generally two-sided structures similar to a ribbon. In the various embodiments described herein, carbon nanotubes can be grown on a tape on one or both sides of the tape. In addition, carbon nanotubes of different types, diameters or lengths can be grown on each side of a tape, which can be advantageous in certain applications.

In some embodiments, fiber materials can be organized into fabric or sheet-like structures. These include, for example, woven fabrics, non-woven fiber mats, meshes and fiber plies, in addition to the tapes described above.

After deposition of the catalytic material, a chemical vapor deposition (CVD)-based process or other process for growing carbon nanotubes can be used to grow carbon nanotubes on the metal substrate. Illustrative processes for carbon nanotube synthesis include, for example, micro-cavity, thermal or plasma-enhanced CVD techniques, laser ablation, arc discharge, flame synthesis and high pressure carbon monoxide (HiPC®) synthesis, all of which are known to those of ordinary skill in the art. In some embodiments, the CVD-based growth process can be plasma-enhanced. In some embodiments, the process for growing carbon nanotubes can take place continuously with the metal substrate being conveyed in a continuous manner through a reactor for synthesizing carbon nanotubes.

In the embodiments described herein, carbon nanotube growth can take place in a continuous (i.e., moving) manner or under batchwise (i.e., static) conditions. In non-limiting embodiments, growth of carbon nanotubes can take place in reactors that are adapted for continuous carbon nanotube growth. Illustrative reactors having such features are described in commonly owned U.S. patent application Ser. No. 12/611,073, filed Nov. 2, 2009, and U.S. Pat. No. 7,261,799, each of which is incorporated herein by reference in its entirety. Although the above reactors are designed for continuously conveying a substrate through the reactor for exposure to carbon nanotube growth conditions, the reactors can also be operated in a batchwise mode with the substrate remaining stationary. Further details of an illustrative carbon nanotube reactor and certain process details for growing carbon nanotubes are set forth hereinafter.

Carbon nanotube growth can be based on a chemical vapor deposition (CVD) process that occurs at elevated temperatures. The specific temperature is a function of catalyst choice, but can typically be in a range of about 500° C. to about 1000° C. In some embodiments, the temperature can be in a range of about 550° C. to about 800° C. In various embodiments, the temperature can influence the carbon nanotube growth rate and/or the carbon nanotube diameters obtained.

In various embodiments, carbon nanotube growth can take place by a CVD-based process, which can be plasma-enhanced. The CVD process can be promoted by a carbon-containing feedstock gas such as, for example, acetylene, ethylene, and/or ethanol. The carbon nanotube synthesis processes generally use an inert gas (e.g., nitrogen, argon, and/or helium) as a primary carrier gas in conjunction with the carbon-containing feedstock gas. The carbon-containing feedstock gas is typically provided in a range from between about 0.1% to about 10% of the total mixture. A substantially inert environment for CVD growth can be prepared by removal of moisture and oxygen from the growth chamber.

A strong plasma-creating electric field can optionally be employed to affect the direction of carbon nanotube growth. A plasma can be generated by providing an electric field during the growth process. By properly adjusting the geometry of the plasma spray and electric field, vertically aligned carbon nanotubes (i.e., perpendicular to the metal surface) can be synthesized. Under certain conditions, even in the absence of a plasma, closely-spaced carbon nanotubes can maintain a substantially vertical growth direction resulting in a dense array of carbon nanotubes resembling a carpet or forest.

In some embodiments, acetylene gas can be ionized to create a jet of cold carbon plasma for carbon nanotube synthesis. The carbon plasma is directed toward the catalyst-laden metal substrate. Thus, in some embodiments, methods for synthesizing carbon nanotubes on a metal substrate include (a) forming a carbon plasma; and (b) directing the carbon plasma onto the catalytic material disposed on the metal substrate.

In some embodiments, a metal substrate can be heated to between about 550° C. and about 800° C. to facilitate carbon nanotube synthesis. To initiate the growth of carbon nanotubes, two or more gases are bled into the reactor: an inert carrier gas (e.g., argon, helium, or nitrogen) and a carbon-containing feedstock gas (e.g., acetylene, ethylene, ethanol or methane).

In some embodiments, carbon nanotube growth can take place in a special rectangular reactor designed for continuous synthesis and growth of carbon nanotubes on fiber materials. Such a reactor is described in commonly-owned, co-pending patent application Ser. No. 12/611,073, incorporated by reference hereinabove. This reactor utilizes atmospheric pressure growth of carbon nanotubes, which facilitates its incorporation in a continuous carbon nanotube growth process. In addition, the reactor can be operated in a batchwise manner with the metal substrate being held stationary, if desired. In some embodiments, carbon nanotubes can be grown via a CVD process at atmospheric pressure and an elevated temperature in the range of about 550° C. and about 800° C. in a multi-zone reactor. The fact that the carbon nanotube synthesis occurs at atmospheric pressure is one factor that facilitates the incorporation of the reactor into a continuous processing line for carbon nanotube growth on the metal substrate. Another advantage consistent with in-line continuous processing using such a multi-zone reactor is that carbon nanotube growth occurs in seconds, as opposed to minutes (or longer), as in other procedures and apparatus configurations typical in the art.

Carbon nanotube synthesis reactors designed in accordance with the above embodiments can include the following features:

Rectangular Configured Synthesis Reactors: The cross-section of a typical carbon nanotube synthesis reactor known in the art is circular. There are a number of reasons for this including, for example, historical reasons (e.g., cylindrical reactors are often used in laboratories) and convenience (e.g., flow dynamics are easy to model in cylindrical reactors, heater systems readily accept circular tubes (e.g., quartz, etc.), and ease of manufacturing. Departing from the cylindrical convention, the present disclosure provides a carbon nanotube synthesis reactor having a rectangular cross section. The reasons for the departure include at least the following:

1) Inefficient Use of Reactor Volume. Since many metal substrates that are to be processed by the reactor are relatively planar (e.g., flat tapes, sheet-like forms, or spread tows or rovings), a circular cross-section is an inefficient use of the reactor volume. This inefficiency results in several drawbacks for cylindrical carbon nanotube synthesis reactors including, for example, a) maintaining a sufficient system purge; increased reactor volume requires increased gas flow rates to maintain the same level of gas purge, resulting in inefficiencies for high volume production of carbon nanotubes in an open environment; b) increased carbon-containing feedstock gas flow rates; the relative increase in inert gas flow for system purge, as per a) above, requires increased carbon-containing feedstock gas flow rates. Consider that the volume of an illustrative 12K glass fiber roving is approximately 2000 times less than the total volume of a synthesis reactor having a rectangular cross-section. In an equivalent cylindrical reactor (i.e., a cylindrical reactor that has a width that accommodates the same planarized glass fiber material as the rectangular cross-section reactor), the volume of the glass fiber material is approximately 17,500 times less than the volume of the reactor. Although gas deposition processes, such as CVD, are typically governed by pressure and temperature alone, volume can have a significant impact on the efficiency of deposition. With a rectangular reactor there is a still excess volume, and this excess volume facilitates unwanted reactions. However, a cylindrical reactor has about eight times that volume available for facilitating unwanted reactions. Due to the greater opportunity for competing reactions to occur, the desired reactions effectively occur more slowly in a cylindrical reactor. Such a slow down in carbon nanotube growth, is problematic for the development of continuous growth processes. Another benefit of a rectangular reactor configuration is that the reactor volume can be decreased further still by using a small height for the rectangular chamber to make the volume ratio better and the reactions even more efficient. In some embodiments disclosed herein, the total volume of a rectangular synthesis reactor is no more than about 3000 times greater than the total volume of a metal substrate being passed through the synthesis reactor. In some further embodiments, the total volume of the rectangular synthesis reactor is no more than about 4000 times greater than the total volume of the metal substrate being passed through the synthesis reactor. In some still further embodiments, the total volume of the rectangular synthesis reactor is less than about 10,000 times greater than the total volume of the metal substrate being passed through the synthesis reactor. Additionally, it is notable that when using a cylindrical reactor, more carbon-containing feedstock gas is required to provide the same flow percent as compared to reactors having a rectangular cross section. It should be appreciated that in some other embodiments, the synthesis reactor has a cross-section that is described by polygonal forms that are not rectangular, but are relatively similar thereto and provide a similar reduction in reactor volume relative to a reactor having a circular cross section; and c) problematic temperature distribution; when a relatively small-diameter reactor is used, the temperature gradient from the center of the chamber to the walls thereof is minimal, but with increased reactor size, such as would be used for commercial-scale production, such temperature gradients increase. Temperature gradients result in product quality variations across the metal substrate (i.e., product quality varies as a function of radial position). This problem is substantially avoided when using a reactor having a rectangular cross-section. In particular, when a planar substrate is used, reactor height can be maintained constant as the size of the substrate scales upward. Temperature gradients between the top and bottom of the reactor are essentially negligible and, as a consequence, thermal issues and the product-quality variations that result are avoided.

2) Gas introduction. Because tubular furnaces are normally employed in the art, typical carbon nanotube synthesis reactors introduce gas at one end and draw it through the reactor to the other end. In some embodiments disclosed herein, gas can be introduced at the center of the reactor or within a target growth zone, symmetrically, either through the sides or through the top and bottom plates of the reactor. This improves the overall carbon nanotube growth rate because the incoming feedstock gas is continuously replenishing at the hottest portion of the system, which is where carbon nanotube growth is most active.

Zoning. Chambers that provide a relatively cool purge zone extend from both ends of the rectangular synthesis reactor. Applicants have determined that if a hot gas were to mix with the external environment (i.e., outside of the rectangular reactor), there would be increased degradation of the metal substrate. The cool purge zones provide a buffer between the internal system and external environments. Carbon nanotube synthesis reactor configurations known in the art typically require that the substrate is carefully (and slowly) cooled. The cool purge zone at the exit of the present rectangular carbon nanotube growth reactor achieves the cooling in a short period of time, as required for continuous in-line processing.

Non-contact, hot-walled, metallic reactor. In some embodiments, a metallic hot-walled reactor (e.g., stainless steel) is employed. Use of this type of reactor can appear counterintuitive because metal, and stainless steel in particular, is more susceptible to carbon deposition (i.e., soot and by-product formation). Thus, most carbon nanotube synthesis reactors are made from quartz because there is less carbon deposited, quartz is easier to clean, and quartz facilitates sample observation. However, Applicants have observed that the increased soot and carbon deposition on stainless steel results in more consistent, efficient, faster, and stable carbon nanotube growth. Without being bound by theory it has been indicated that, in conjunction with atmospheric operation, the CVD process occurring in the reactor is diffusion limited. That is, the carbon nanotube-forming catalyst is “overfed;” too much carbon is available in the reactor system due to its relatively higher partial pressure (than if the reactor was operating under partial vacuum). As a consequence, in an open system—especially a clean one—too much carbon can adhere to the particles of carbon nanotube-forming catalyst, compromising their ability to synthesize carbon nanotubes. In some embodiments, the rectangular reactor is intentionally run when the reactor is “dirty,” that is with soot deposited on the metallic reactor walls. Once carbon deposits to a monolayer on the walls of the reactor, carbon will readily deposit over itself. Since some of the available carbon is “withdrawn” due to this mechanism, the remaining carbon feedstock, in the form of radicals, reacts with the carbon nanotube-forming catalyst at a rate that does not poison the catalyst. Existing systems run “cleanly” which, if they were open for continuous processing, would produce a much lower yield of carbon nanotubes at reduced growth rates.

Although it is generally beneficial to perform carbon nanotube synthesis “dirty” as described above, certain portions of the apparatus (e.g., gas manifolds and inlets) can nonetheless negatively impact the carbon nanotube growth process when soot creates blockages. In order to combat this problem, such areas of the carbon nanotube growth reaction chamber can be protected with soot inhibiting coatings such as, for example, silica, alumina, or MgO. In practice, these portions of the apparatus can be dip-coated in these soot inhibiting coatings. Metals such as INVAR (a nickel-steel alloy commercially available from ArcelorMittal) can be used with these coatings as INVAR has a similar CTE (coefficient of thermal expansion) ensuring proper adhesion of the coating at higher temperatures, preventing the soot from significantly building up in critical zones.

Combined Catalyst Reduction and Carbon Nanotube Synthesis. In the carbon nanotube synthesis reactor disclosed herein, both catalyst reduction and carbon nanotube growth can occur within the reactor. In a typical process known in the art, a reduction step typically takes 1-12 hours to perform. Both operations can occur in a reactor in accordance with the present disclosure due, at least in part, to the fact that carbon-containing feedstock gas is introduced at the center of the reactor, not the end as would be typical in the art using cylindrical reactors. The reduction process occurs as the metal substrate enters the heated zone. By this point, the gas has had time to react with the walls and cool off prior to reducing the catalyst (via hydrogen radical interactions). It is this transition region where the reduction can occur. At the hottest isothermal zone in the system, carbon nanotube growth occurs, with the greatest growth rate occurring proximal to the gas inlets near the center of the reactor.

It is understood that modifications which do not substantially affect the activity of the various embodiments of this invention are also included within the definition of the invention provided herein. Accordingly, the following Examples are intended to illustrate but not limit the present invention.

### Example 1

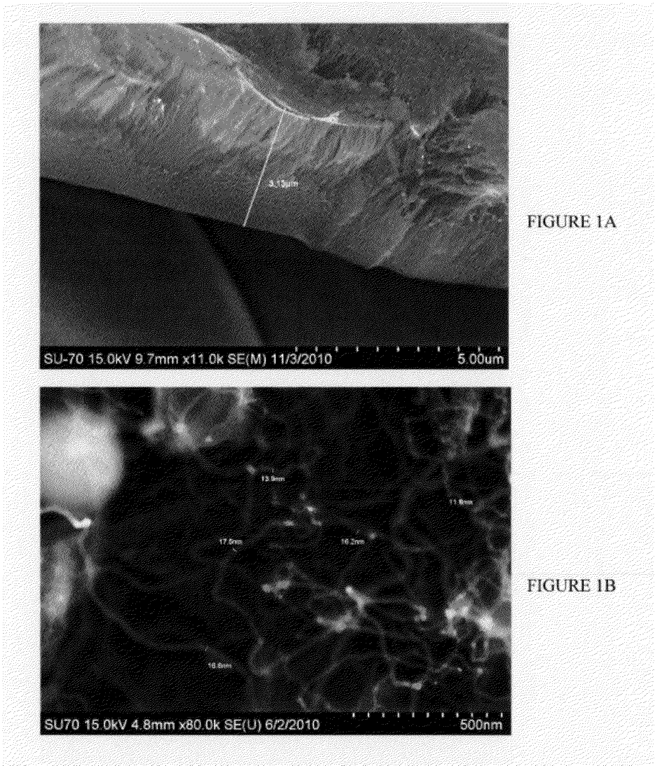

Carbon Nanotube Growth Under Static CVD Conditions at 750° C. on a Copper Substrate Using a Palladium Catalyst. For this example, a palladium dispersion in water at a concentration of 0.5 wt % was used to deposit the catalytic material. In this case, a non-catalytic material was not deposited on the copper substrate. The 0.5 wt % palladium dispersion was applied to an electroplated copper foil substrate by a dip coating process to form a thin liquid layer. The substrate was then dried for 5 minutes with a heat gun at 600° F. Carbon nanotubes were grown under carbon nanotube growth conditions using the reactor described above, with the exception that the reactor was run with the substrate held stationary, rather than being continuously conveyed through the reactor. Under static growth conditions using this catalyst system, carbon nanotubes ranging from 5 nm to 30 nm in diameter and from 0.1 vim to 300 μm in length were obtained, depending on the growth temperature and the residence time in the reactor. Carbon nanotube growth conducted under static chemical vapor deposition conditions for 5 minutes at a temperature of 750° C. produced carbon nanotubes of about 3 μm in length that ranged from 18 nm to 25 nm in diameter. FIGS. 1A and 1B show illustrative SEM images of carbon nanotubes grown on a copper substrate using a palladium catalyst under static chemical vapor deposition conditions for 5 minutes at a temperature of 750° C. FIG. 1A is at 11,000× magnification, and FIG. 1B is at 80,000× magnification.

### Example 2

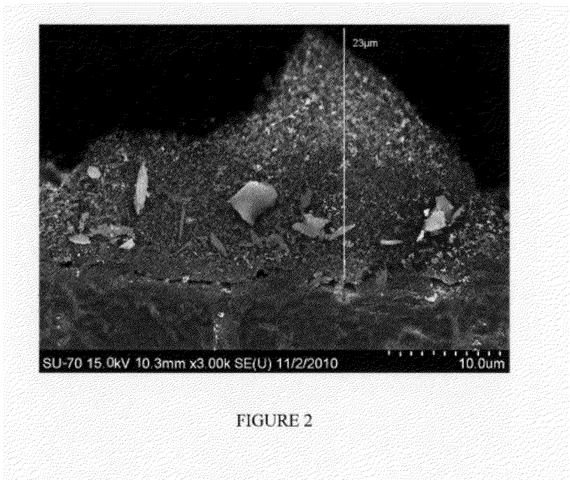

Carbon Nanotube Growth Under Continuous CVD Conditions at 750° C. on a Copper Substrate Using a Palladium Catalyst. The carbon nanotube growth of EXAMPLE 1 was repeated with the exception that the copper substrate was conveyed through the reactor at a processing speed of 1 ft/min during its exposure time to the carbon nanotube growth conditions. Under continuous carbon nanotube growth conditions, carbon nanotubes having lengths up to 23 μm and a 15 nm average diameter were obtained. FIG. 2 shows an illustrative SEM image of carbon nanotubes grown on a copper substrate using a palladium catalyst under continuous chemical vapor deposition conditions for 1 minute at a temperature of 750° C. and a linespeed of 1 ft/min, which is equivalent to 1 minute of carbon nanotube growth time. In FIG. 2, the magnification is 3,000×. Thus, significantly longer carbon nanotubes were obtained under continuous carbon nanotube growth conditions than were obtained when the reactor was run in a static manner.

### Example 3

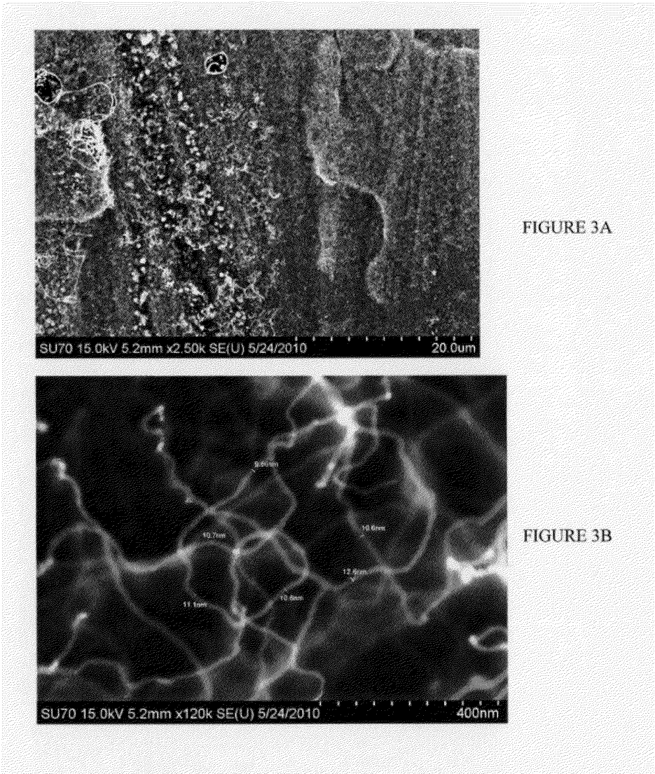

Carbon Nanotube Growth Under Static CVD Conditions at 750° C. on a Copper Substrate Using an Iron Catalyst and a Non-Catalytic Material. The carbon nanotube growth of EXAMPLE 1 was repeated, except a non-catalytic material was deposited on the metal substrate and an iron nanoparticle catalyst was substituted for palladium. A 4 vol % solution of Accuglass T-11 Spin-On Glass (Honeywell International, Inc., Morristown, N.J. ) in isopropanol was applied to an electroplated copper foil metal substrate via a dip coating process. The copper substrate was thereafter dried for 5 seconds at 600° F. using a heat gun. A catalytic solution of 0.09 wt % iron nanoparticles (8 nm diameter) in hexane solvent was applied by a dip coating process, and the copper substrate was dried for 5 seconds using a stream of compressed air. Under static growth conditions using this catalyst system, carbon nanotubes ranging from 5 nm to 15 nm in diameter and from 0.1 μm to 100 μm in length were obtained, depending on the growth temperature and the residence time in the reactor. Carbon nanotube growth conducted under static chemical vapor deposition conditions for 5 minutes at a temperature of 750° C. produced carbon nanotubes of about 3 μm in length that ranged from 8 nm to 15 nm in diameter. FIGS. 3A and 3B show illustrative SEM images of carbon nanotubes grown on a copper substrate using an iron nanoparticle catalyst under static chemical vapor deposition conditions for 5 minutes at a temperature of 750° C., where the iron nanoparticle catalyst was deposited over a layer of non-catalytic Accuglass T-11 Spin-On Glass. FIG. 3A is at 2,500× magnification, and FIG. 3B is at 120,000× magnification.

### Example 4

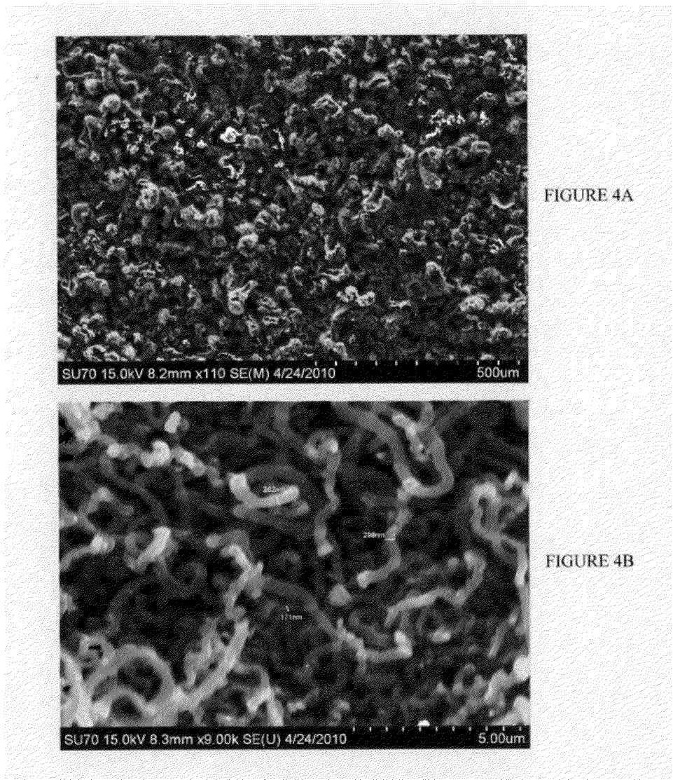

Carbon Nanotube Growth Under Static CVD Conditions at 750° C. on a Copper Substrate Using an Iron Catalyst and a Non-Catalytic Material. The carbon nanotube growth of EXAMPLE 3 was repeated with the exception that the order of addition of the non-catalytic material and the iron nanoparticle catalyst were reversed. That is, the iron nanoparticle catalyst solution was deposited on the metal substrate by dip coating, and the non-catalytic material was added by dip coating thereafter. In this case, the concentration of the iron nanoparticle catalyst solution was 0.9 wt %, and the concentration of Accuglass T-11 Spin-On Glass in isopropanol was 1 vol %. Even when the catalyst was applied under the non-catalytic material, the iron nanoparticles were still able to mediate carbon nanotube growth. Carbon nanotube growth conducted under static chemical vapor deposition conditions for 30 minutes at a temperature of 750° C. produced carbon nanotubes and carbon nanofibers of about 50 μm in length that ranged from 150 nm to 300 nm in diameter. FIGS. 4A and 4B show illustrative SEM images of carbon nanotubes and carbon nanofibers grown on a copper substrate using an iron nanoparticle catalyst under static chemical vapor deposition conditions for 30 minutes at a temperature of 750° C., where the iron nanoparticle catalyst was deposited under a layer of non-catalytic Accuglass T-11 Spin-On Glass. FIG. 4A is at 110× magnification, and FIG. 4B is at 9,000× magnification. In this case, the increase in carbon nanotube and carbon nanofiber diameter can primarily be attributed to the larger concentration of iron nanoparticles used as well as a longer growth time.

### Example 5

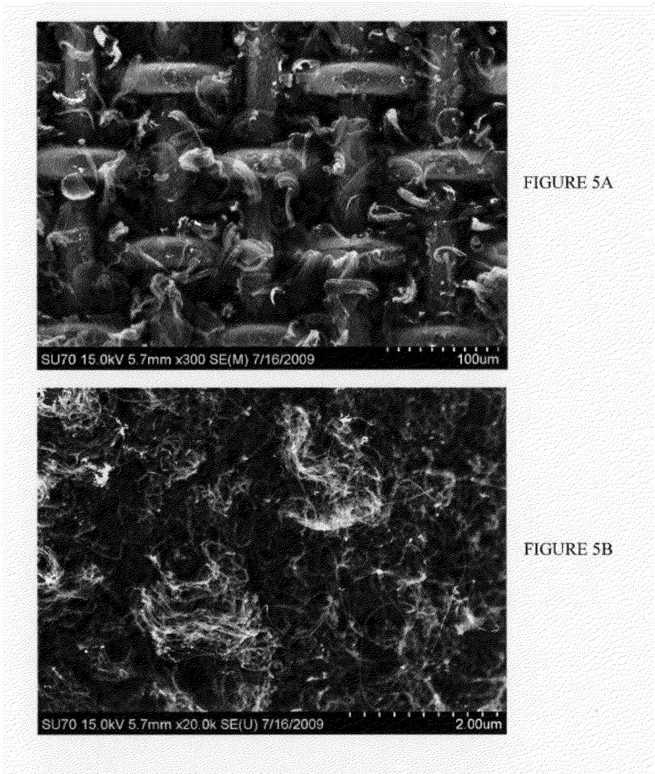

Carbon Nanotube Growth Under Continuous CVD Conditions at 800° C. on a Stainless Steel Wire Mesh Substrate Using an Iron Catalyst and a Non-Catalytic Material. The carbon nanotube growth of EXAMPLE 4 was repeated with the exception that a stainless steel wire mesh substrate was conveyed through the reactor at a processing speed of 2 ft/min during its exposure time to the carbon nanotube growth conditions at a temperature of 800° C. In this case, the concentration of the iron nanoparticle catalyst solution was 0.027 wt %, and the concentration of Accuglass T-11 Spin-On Glass in isopropanol was 2.5 vol %. Under continuous carbon nanotube growth conditions, carbon nanotubes having lengths up to about 50 μm and a 15 nm average diameter were obtained. FIGS. 5A and 5B show illustrative SEM images of carbon nanotubes grown on a stainless steel wire mesh substrate using an iron nanoparticle catalyst under continuous chemical vapor deposition conditions at a temperature of 800° C. and a linespeed of 2 ft/min, which is equivalent to 30 seconds of carbon nanotube growth time, where the iron nanoparticle catalyst was deposited under a layer of non-catalytic Accuglass T-11 Spin-On Glass. FIG. 5A is at 300× magnification, and FIG. 5B is at 20,000× magnification.

### Example 6

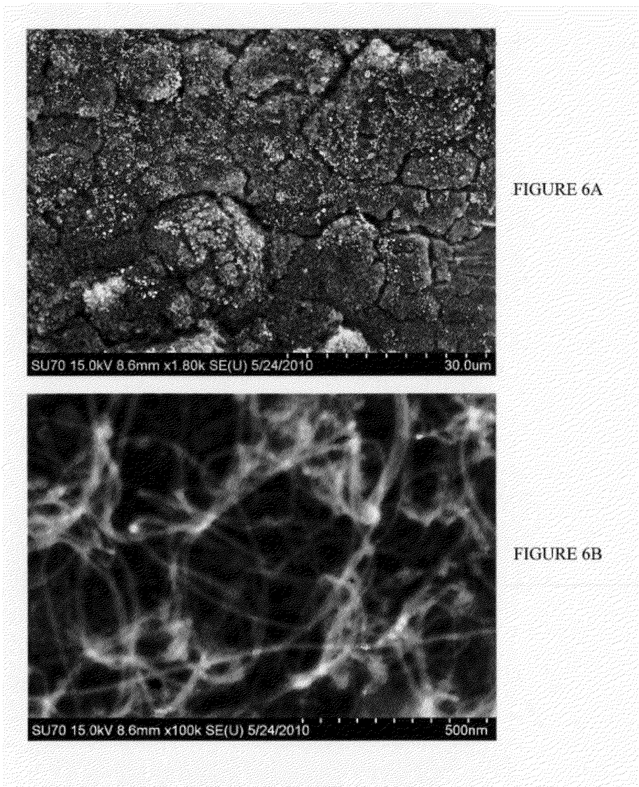

Carbon Nanotube Growth Under Static CVD Conditions at 750° C. on a Copper Substrate Using an Iron Nitrate Catalyst and a Non-Catalytic Material. The carbon nanotube growth of EXAMPLE 3 was repeated with the exception that iron nitrate nonahydrate was substituted as the catalyst and aluminum nitrate nonahydrate was substituted as the non-catalytic material Further, the iron nitrate nonahydrate and the aluminum nitrate nonahydrate were added concurrently. That is, the iron nitrate nonahydrate catalytic material and the aluminum nitrate nonahydrate non-catalytic material were combined into a single solution and deposited on the copper substrate concurrently by dip coating. In this case, the concentration of the iron nitrate catalyst solution was 60 mM in isopropanol, and the concentration of aluminum nitrate in the same solution was also 60 mM. Even when the catalytic material was applied concurrently with the non-catalytic material, the iron catalyst was still able to mediate carbon nanotube growth. Carbon nanotube growth conducted under static chemical vapor deposition conditions for 5 minutes at a temperature of 750° C. produced carbon nanotubes of up to about 75 μm in length that ranged from 15 nm to 25 nm in diameter. FIGS. 6A and 6B show illustrative SEM images of carbon nanotubes grown on a copper substrate using an iron nitrate catalyst under static chemical vapor deposition conditions for 5 minutes at a temperature of 750° C., where the iron nitrate catalyst was deposited concurrently with a non-catalytic aluminum nitrate material. FIG. 6A is at 1,800× magnification, and FIG. 6B is at 100,000× magnification

Although the invention has been described with reference to the disclosed embodiments, those of ordinary skill in the art will readily appreciate that these only illustrative of the invention. It should be understood that various modifications can be made without departing from the spirit of the invention.

What is claimed is:

1. A continuous carbon nanotube growth process conducted in a reactor for synthesizing carbon nanotubes and having carbon nanotube growth conditions therein, the method comprising:
depositing a catalytic material on a metal substrate to form a catalyst-laden metal substrate;
depositing a non-catalytic material on the metal substrate;
wherein the non-catalytic material is deposited prior to, after or concurrently with the catalytic material;
conveying the catalyst-laden metal substrate through the reactor in a continuous manner; and
growing carbon nanotubes on the catalyst-laden metal substrate.

2. The continuous carbon nanotube growth process of claim 1, wherein the catalytic material comprises a catalyst or a catalyst precursor.

3. The continuous carbon nanotube growth process of claim 2, wherein the catalytic material is deposited prior to the non-catalytic material.

4. The continuous carbon nanotube growth process of claim 2, wherein the catalytic material is deposited after the non-catalytic material.

5. The continuous carbon nanotube growth process of claim 2, wherein the catalytic material is deposited concurrently with the non-catalytic material.

6. The continuous carbon nanotube growth process of claim 2, wherein the catalytic material and the non-catalytic material are deposited by a technique selected from the group consisting of spray coating, dip coating and combinations thereof.

7. The continuous carbon nanotube growth process of claim 2, wherein the catalytic material comprises a transition metal salt selected from the group consisting of a transition metal nitrate, a transition metal acetate, a transition metal chloride, and combinations thereof.

8. The continuous carbon nanotube growth process of claim 7, wherein the transition metal salt is selected from the group consisting of iron (II) nitrate, iron (III) nitrate, cobalt (III) nitrate, nickel (II) nitrate, copper (II) nitrate, iron (II) acetate, iron (III) acetate, cobalt (III) acetate, nickel (II) acetate, copper (II) acetate, iron (II) chloride, iron (III) chloride, cobalt (III) chloride, nickel (II) chloride, copper (II) chloride, and combinations thereof.

9. The continuous carbon nanotube growth process of claim 2, wherein catalytic material is selected from the group consisting of palladium, FeO, Fe₂O₃, Fe₃O₄, and combinations thereof.

10. The continuous carbon nanotube growth process of claim 2, wherein the non-catalytic material is selected from the group consisting of an aluminum salt, a glass, a silicate, a silane, and combinations thereof.

11. The continuous carbon nanotube growth process of claim 10, wherein the aluminum salt is selected from the group consisting of aluminum nitrate, aluminum acetate, and combinations thereof.

12. The continuous carbon nanotube growth process of claim 2, wherein the catalytic material and the non-catalytic material are deposited from at least one solution.

13. The continuous carbon nanotube growth process of claim 12, wherein the catalytic material and the non-catalytic material each have a concentration ranging between about 0.1 mM and about 1.0 M in the at least one solution.

14. The continuous carbon nanotube growth process of claim 12, wherein the catalytic material and the non-catalytic material each have a concentration ranging between about 50 mM and about 1.0 M in the at least one solution.

15. The continuous carbon nanotube growth process of claim 12, wherein a molar ratio of the non-catalytic material to the catalytic material is at most about 6:1.

16. The continuous carbon nanotube growth process of claim 12, wherein a molar ratio of the non-catalytic material to the catalytic material is at most about 2:1.

17. The continuous carbon nanotube growth process of claim 1, wherein the metal substrate is selected from the group consisting of copper, tungsten, platinum, titanium, iron, steel alloys, stainless steel alloys, nickel, nickel-chromium alloys, nickel-copper alloys, gold, silver, brass alloys, and combinations thereof.

18. The continuous carbon nanotube growth process of claim 1, wherein the catalytic material and the non-catalytic material comprise a catalyst coating having a thickness ranging between about 10 nm and about 1 μm.

19. A carbon nanotube growth process conducted in a reactor for synthesizing carbon nanotubes and having carbon nanotube growth conditions therein, the method comprising:
depositing a catalytic material on a metal substrate from a solution to form a catalyst-laden metal substrate;
wherein the metal substrate has a melting point in excess of about 800° C.; and
growing carbon nanotubes on the catalyst-laden metal substrate;
wherein the catalyst-laden metal substrate remains stationary or is conveyed through the reactor in a continuous manner while growing carbon nanotubes thereon.

20. The carbon nanotube growth process of claim 19, wherein the catalytic material comprises a catalyst precursor.

21. The carbon nanotube growth process of claim 20, further comprising:
forming catalytic nanoparticles from the catalyst precursor while the catalyst-laden metal substrate is being conveyed through the reactor.

22. The carbon nanotube growth process of claim 20, further comprising:
forming catalytic nanoparticles from the catalyst precursor prior to conveying the catalyst-laden metal substrate through the reactor.

23. The carbon nanotube growth process of claim 22, wherein forming catalytic nanoparticles comprising heating the catalyst precursor on the catalyst-laden metal substrate.

24. The carbon nanotube growth process of claim 20, further comprising:
depositing a non-catalytic material on the metal substrate from a solution;
wherein the non-catalytic material is deposited prior to, after or concurrently with the catalytic material.

25. The carbon nanotube growth process of claim 24, further comprising:
conveying the catalyst-laden metal substrate through the reactor in a continuous manner.

26. The carbon nanotube growth process of claim 24, wherein the catalytic material and the non-catalytic material are in a first solution and a second solution, respectively, and the catalytic material is deposited prior to the non-catalytic material.

27. The carbon nanotube growth process of claim 24, wherein the catalytic material and the non-catalytic material are in a first solution and a second solution, respectively, and the catalytic material is deposited after the non-catalytic material.

28. The carbon nanotube growth process of claim 24, wherein the catalytic material and the non-catalytic material are in the same solution and are deposited concurrently.

29. The carbon nanotube growth process of claim 24, wherein the catalytic material comprises a transition metal salt selected from the group consisting of a transition metal nitrate, a transition metal acetate, a transition metal chloride, and combinations thereof.

30. The carbon nanotube growth process of claim 24, wherein the non-catalytic material comprises a substance selected from the group consisting of an aluminum salt, a glass, a silicate, a silane, and combinations thereof.

31. The carbon nanotube growth process of claim 24, wherein the catalytic material and the non-catalytic material comprise a catalyst coating having a thickness ranging between about 10 nm and about 1 μm.

32. The carbon nanotube growth process of claim 19, wherein the catalytic material comprises a transition metal salt selected from the group consisting of a transition metal nitrate, a transition metal acetate, a transition metal chloride, and combinations thereof.

33. A continuous carbon nanotube growth process conducted in a reactor for synthesizing carbon nanotubes and having carbon nanotube growth conditions therein, the method comprising:
depositing a catalyst precursor on a metal substrate from a solution to form a catalyst-laden metal substrate;
depositing a non-catalytic material on the metal substrate from a solution;
wherein the non-catalytic material is deposited prior to, after or currently with the catalyst precursor; and
conveying the catalyst-laden metal substrate through the reactor in a continuous manner while growing carbon nanotubes thereon.

34. A metal substrate having carbon nanotubes grown thereon prepared by the continuous carbon nanotube growth process of claim 33.
